(19) United States
(12) Patent Application Publication
(10) Pub. No.: US 2025/0294994 A1
(43) Pub. Date: Sep. 18, 2025

(54) DISPLAY DEVICE

(71) Applicant: Samsung Display Co., Ltd., Yongin-si (KR)

(72) Inventors: MINSEOK KIM, Yongin-si (KR); SONGYI KIM, Yongin-si (KR); SUJIN KIM, Yongin-si (KR); DONG GYU BAECK, Yongin-si (KR); YONGSEOK CHOI, Yongin-si (KR)

(73) Assignee: Samsung Display Co., Ltd., Yongin-si (KR)

(21) Appl. No.: 19/010,349

(22) Filed: Jan. 6, 2025

(30) Foreign Application Priority Data
Mar. 12, 2024 (KR) 10-2024-0034441

(51) Int. Cl. H10K 59/38

(52) U.S. Cl. CPC H10K 59/38

(57) ABSTRACT

A display device includes a display element layer including a light emitting element, and a light control layer disposed on the display element layer and including a first control part including first quantum dots and a second light control part separated from the first light control part in a direction perpendicular to a thickness direction and including second quantum dots and a metal nanomaterial. The first quantum dots emit light in a wavelength range of about 630 nm to about 750 nm, the second quantum dots emit light in a wavelength range of about 495 nm to about 570 nm, and the metal nanomaterial absorbs light in a wavelength range of about 550 nm to about 590 nm.

### CROSS-REFERENCE TO RELATED APPLICATIONS

This application claims priority to and benefits of Korean Patent Application No. 10-2024-0034441 under 35 U.S.C. § 119, filed on Mar. 12, 2024, in the Korean Intellectual Property Office (KIPO), the entire contents of which are incorporated herein by reference.

### BACKGROUND

### 1. Technical Field

The disclosure herein relates to a display device including quantum dots that convert light.

### 2. Description of the Related Art

A display device includes a transmissive display device that selectively transmits source light generated from a light source and an emissive display device that generates source light from the display device itself. A display device may include different types of light control parts depending on pixels to generate a color image. The light control part may transmit only a portion of the wavelength range of the source light or convert the color of the source light. Some light control parts may change the characteristics of light without changing the color of the source light. Quantum dot materials are used in the light control part of display devices, and technology development is needed to improve the display quality of display devices.

### SUMMARY

An object of the disclosure is to provide a display device with improved display quality by reducing reflectance.

According to an embodiment, a display device may include a display element layer including a light emitting element, and a light control layer disposed on the display element layer and including a first light control part including first quantum dots, and a second light control part that is separated from the first light control part in a direction that is perpendicular to a thickness direction and including second quantum dots and a metal nanomaterial. The first quantum dots may emit light in a wavelength range of about 630 nm to about 750 nm, the second quantum dots may emit light in a wavelength range of about 495 nm to about 570 nm, and the metal nanomaterial may absorb light in a wavelength range of about 550 nm to about 590 nm.

In an embodiment, the metal nanomaterial may emit light in a wavelength range of about 550 nm to about 630 nm.

In an embodiment, the metal nanomaterial may have a light emitting central wavelength in a wavelength range of about 580 nm to about 630 nm.

In an embodiment, the metal nanomaterial may include at least one of yellow quantum dots, orange quantum dots, gold nanoparticles, silver nanoparticles, and silver nanoplates.

In an embodiment, a diameter of each of the gold nanoparticles, the silver nanoparticles, and the silver nanoplates may be in a range of about 10 nm to about 800 nm.

In an embodiment, a weight of the metal nanomaterial may be in a range of about 0.1 wt % to about 15 wt % on a basis of 100 wt % of a total weight of the second light control part.

In an embodiment, an absorption spectrum of the metal nanomaterial may include a wavelength variation region in a wavelength range of about 520 nm to about 540 nm, and the wavelength variation region may be a region with a concave shape in the absorption spectrum, where an absorbance decreases and then increases.

In an embodiment, a weight of the second quantum dots may be in a range of about 10 wt % to about 50 wt % on a basis of 100 wt % of a total weight of the second light control part.

In an embodiment, each of the first light control part and the second light control part may further include a scatterer, and the scatterer may include at least one of TiO₂, SiO₂, BaTiO₃, BaO, ZnS, ZnO, Al2O₃, and hollow silica.

In an embodiment, a weight of the scatterer may be in a range of about 0 wt % to about 15 wt % on a basis of 100 wt % of a total weight of the second light control part.

In an embodiment, the scatterer may include a plurality of scatterers, and a median diameter (D50) of the plurality of scatterers may be in a range of about 50 nm to about 500 nm.

In an embodiment, each of the first quantum dots, the second quantum dots, and the metal nanomaterial may include at least one of a II-VI group semiconductor compound, a I-II-VI group semiconductor compound, a II-IV-VI group compound, a I-II-IV-VI group semiconductor compound, a III-V group semiconductor compound, a III-II-V group semiconductor compound, a III-VI group semiconductor compound, a I-III-VI group semiconductor compound, a IV-VI group semiconductor compound, a II-IV-V group semiconductor compound, a IV group semiconductor compound, a IV group element, a mixture thereof, and a compound thereof.

In an embodiment, each of the first quantum dots and the second quantum dots may include a core and a shell surrounding the core.

In an embodiment, the light emitting element may include a first electrode, a second electrode disposed on the first electrode, and an emission layer that is disposed between the first electrode and the second electrode and emits source light including blue light and green light.

According to an embodiment of the disclosure, a display device may include a display element layer providing source light, and a light control layer disposed on the display element layer and including a first light control part including red quantum dots, and a second light control part that is separated from the first light control part in a direction that is perpendicular to a thickness direction and including green quantum dots and a metal nanomaterial. The metal nanomaterial may include at least one of yellow quantum dots, orange quantum dots, gold nanoparticles, silver nanoparticles, and silver nanoplates.

In an embodiment, the metal nanomaterial may absorb light in a wavelength range of about 550 nm to about 590 nm.

In an embodiment, an absorption spectrum of the metal nanomaterial may include a wavelength variation region in a wavelength range of about 520 nm to about 540 nm, and the wavelength variation region may be a region with a concave shape in the absorption spectrum, where an absorbance decreases and increases.

In an embodiment, the metal nanomaterial may have a light emitting central wavelength in a wavelength range of about 580 nm to about 630 nm.

In an embodiment, a diameter of each of the gold nanoparticles, the silver nanoparticles, and the silver nanoplates may be in a range of about 10 nm to about 800 nm.

In an embodiment, a weight of the metal nanomaterial may be in a range of about 0.1 wt % to about 15 wt % on a basis of 100 wt % of a total weight of the second light control part.

In an embodiment, the source light may include blue light and green light.

In an embodiment, each of the first light control part and the second light control part may further include a scatterer, and the scatterer may include at least one of TiO₂, SiO₂, BaTiO₃, BaO, ZnS, ZnO, Al₂O₃, and hollow silica.

According to an embodiment of the disclosure, a display device divided into a red pixel area, a green pixel area, and a blue pixel area may include a display element layer including a light emitting element, and a light control layer disposed on the display element layer and including a first light control part including first quantum dots and corresponding to the red pixel area, a second light control part including second quantum dots and a metal nanomaterial, and corresponding to the green pixel area, and a third light control part corresponding to the blue pixel area. The metal nanomaterial may absorb light in a wavelength range of about 550 nm to about 590 nm.

In an embodiment, the metal nanomaterial may include at least one of yellow quantum dots, orange quantum dots, gold nanoparticles, silver nanoparticles, and silver nanoplates.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain principles of the disclosure. In the drawings:

FIG. 1 is a perspective view showing a display device of an embodiment;

FIG. 2 is a schematic cross-sectional view showing a portion corresponding to line I-I′ in FIG. 1;

FIG. 3 is a plan view showing a portion of a display device according to an embodiment;

FIG. 4 is a plan view showing a portion of a display device according to an embodiment;

FIG. 5A is a schematic cross-sectional view showing a portion corresponding to line II-II′ in FIG. 4;

FIG. 5B is a schematic cross-sectional view showing a display device of an embodiment;

FIG. 6 is a schematic diagram schematically showing a quantum dot according to an embodiment;

FIG. 7 is a graph showing the absorbance of a metal nanomaterial according to an embodiment;

FIG. 8 is a graph showing luminous intensity in accordance with wavelength in an example;

FIG. 9 is a graph showing reflectance in accordance with wavelength in a comparative example and examples; and

FIG. 10 is a graph showing reflectance in accordance with wavelength in a comparative example and examples.

### DETAILED DESCRIPTION OF THE EMBODIMENTS

The disclosure may have various modifications and may be embodied in different forms, and embodiments will be explained in detail with reference to the accompanying drawings. The disclosure may, however, be embodied in different forms and should not be construed as limited to the embodiments set forth herein. Rather, all modifications, equivalents, and substituents which are included in the spirit and technical scope of the disclosure should be included in the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

It will be understood that, although the terms first, second, etc. may be used herein to describe various elements, these elements should not be limited by these terms. These terms are only used to distinguish one element from another element. For example, a first element could be termed a second element without departing from the scope of the disclosure. Similarly, a second element could be termed a first element. As used herein, the singular forms are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

It will be further understood that the terms “comprises” or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this disclosure belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly defined so herein.

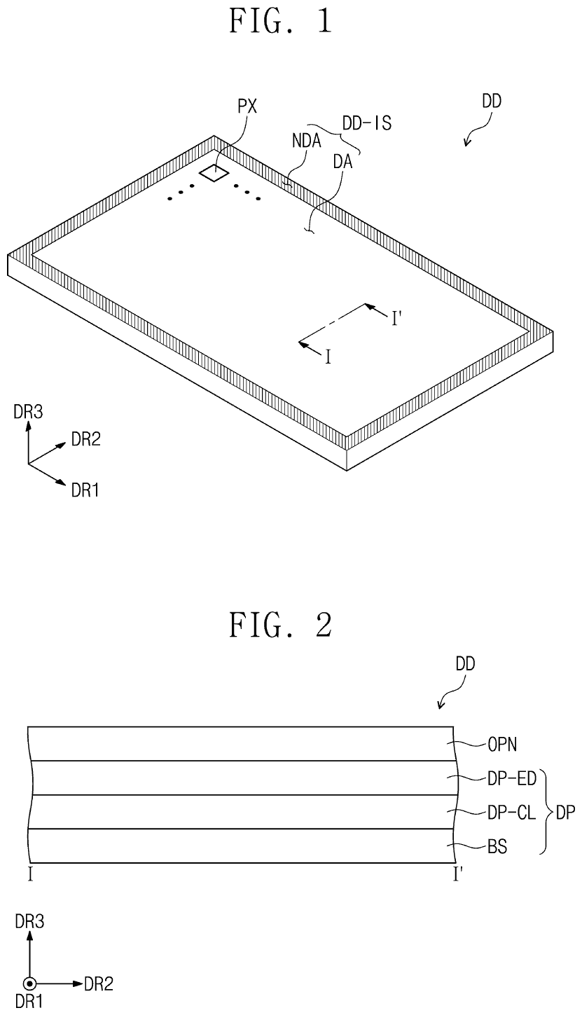

Hereinafter, a display device according to an embodiment of the disclosure will be explained referring to the drawings. FIG. 1 is a perspective view showing a display device DD of an embodiment.

Referring to FIG. 1, the display device DD of an embodiment may be a device activated by electrical signals. For example, the display device DD may be a large-sized device such as a television, a monitor and an external billboard. For example, the display device DD may be small- or medium-sized devices such as a personal computer, a laptop computer, a personal digital terminal, a car navigation unit, a game console, a smart phone, a tablet and a camera. However, the disclosure is not limited thereto, and the display device DD may be employed as other display devices unless deviated from the disclosure.

The display device DD may display images (or videos) through a display surface DD-IS. The display surface DD-IS may be parallel to a plane defined by a first directional axis DR1 and a second directional axis DR2. The display surface DD-IS may include a display area DA and a non-display area NDA.

In the display area DA, a pixel PX may be disposed, and in the non-display area NDA, the pixel PX may not be disposed. The non-display area NDA may be defined along the edge of the display surface DD-IS. The non-display area NDA may surround the display area DA. However, the disclosure is not limited thereto, and the non-display area NDA may be omitted, or the non-display area NDA may be disposed only at one side of the display area DA.

In FIG. 1, a display device DD provided with a planar display surface DD-IS is shown, but the disclosure is not limited thereto. The display device DD may include a curve-type display surface or a three-dimensional display surface. The three-dimensional display surface may include multiple display areas facing other directions from each other.

In FIG. 1 and the drawings below, a first directional axis DR1 to a third directional axis DR3 are shown, and the directions indicated by the first to third directional axes DR1, DR2 and DR3, explained in the description have relative concept and may be converted to other directions. The directions indicated by the first to third directional axes DR1, DR2 and DR3 may be first to third directions, and the same reference symbols may be used. In the description, the first directional axis DR1 and the second directional axis DR2 may be orthogonal to each other, and the third directional axis DR3 may be a normal direction to a plane defined by the first directional axis DR1 and the second directional axis DR2.

In the description, a plane may be defined by the first directional axis DR1 and the second directional axis DR2, and a cross-section may mean a surface perpendicular to the plane defined by the first directional axis DR1 and the second directional axis DR2 and parallel to the third directional axis DR3. The thickness direction of the display device DD may be a direction parallel to the third direction DR3 that is a normal direction to the plane defined by the first direction DR1 and the second direction DR2.

In the description, the top surface (or front surface) and bottom surface (or rear surface) of the members constituting the display device DD may be defined based on the third direction DR3. For example, for one element, a surface relatively adjacent to the display surface DD-IS among two facing surfaces based on the third direction DR3 may be defined as a front surface (or top surface), and a surface separated apart from the display surface DD-IS with the front surface (or top surface) therebetween, may be defined as a rear surface (or bottom surface). In the description, an upper part (or upper side) or a lower part (or lower side) may be defined based on the third direction DR3, and the upper part (or upper side) may be defined as a direction close to the display surface DD-IS, and the lower part (lower side) may be defined as a direction away from the display surface DD-IS.

In the description, one element is “disposed directly/formed directly on” another element, may mean that there are no third elements between the one element and another element. For example, one element is “disposed directly/formed directly on” another element, may mean that the one element and another element make “contact” from each other.

FIG. 2 is a schematic cross-sectional view showing a portion corresponding to line I-I′. FIG. 2 may be a cross-sectional view schematically showing a display device DD according to an embodiment.

Referring to FIG. 2, the display device DD may include a display panel DP and an optical panel OPN disposed on the display panel DP. The display panel DP may include a base substrate BS, a circuit layer DP-CL disposed on the base substrate BS, and a display element layer DP-ED disposed on the circuit layer DP-CL.

The base substrate BS may be a member providing a base surface for disposing the circuit layer DP-CL and the display element layer DP-ED. The circuit layer DP-CL may include at least one insulating layer and a circuit element. The circuit element may include a signal line, a driving circuit of a pixel or the like. The circuit layer DP-CL may be formed through a forming process of an insulating layer, a semiconductor layer and a conductive layer by coating, deposition, or the like, and a patterning process of the insulating layer, the semiconductor layer and the conductive layer by a photolithography process.

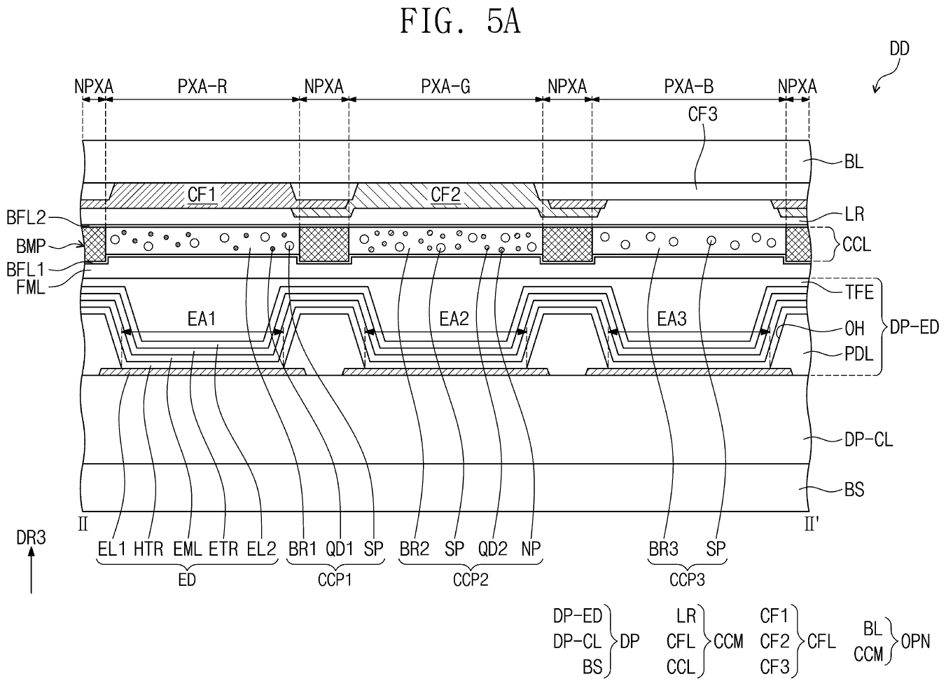

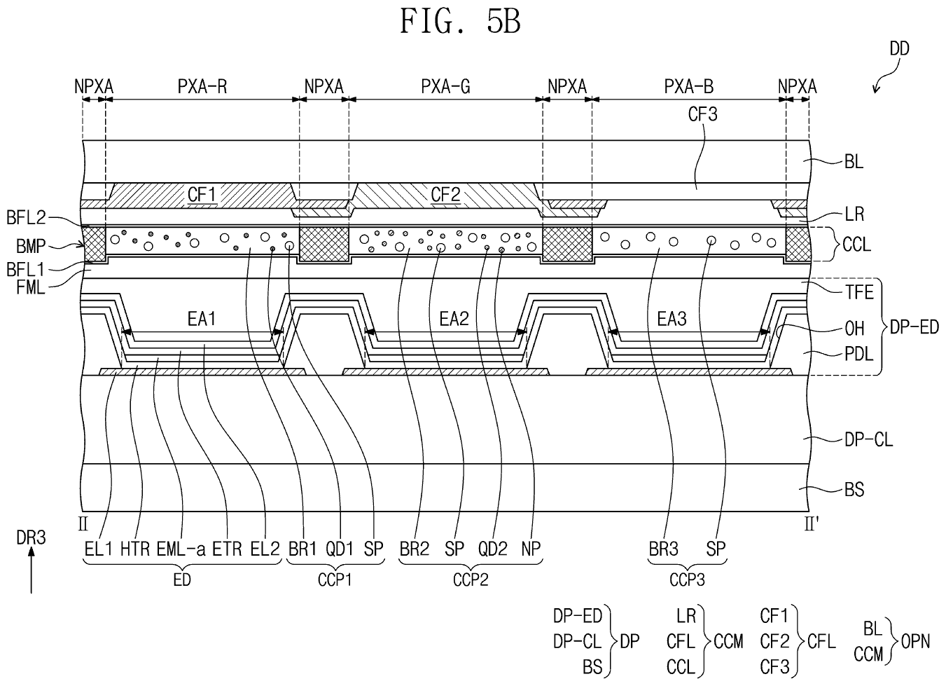

The display element layer DP-ED may include a light emitting element ED (FIGS. 5A and 5B), which will be explained below. The display element layer DP-ED may provide source light emitted from the light emitting element ED (FIGS. 5A and 5B).

The optical panel OPN may transmit the source light provided from the display element layer DP-ED or convert into light of a different color from the source light. The display device DD including the optical panel OPN may show excellent display quality.

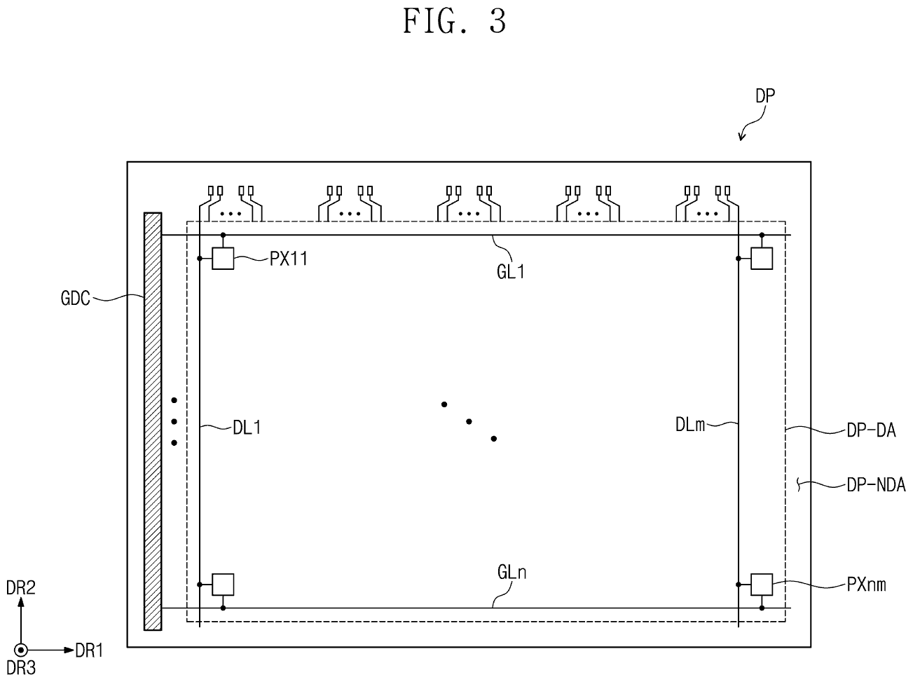

FIG. 3 is a plan view showing a display panel DP according to an embodiment. In FIG. 3 the planar arrangement relationship of signal lines GL1 to GLn and DL1 to DLm, pixels PX11 to PXnm, and a gate driving circuit GDC, is shown as an embodiment.

The display panel DP may include an active area DP-DA and a peripheral area DP-NDA adjacent to the active area DP-DA. In the active area DP-DA, pixels PX11 to PXnm may be disposed, and in the peripheral area DP-NDA, a gate driving circuit GDC may be disposed. The active area DP-DA may correspond to a display area DA shown in FIG. 1. The peripheral area DP-NDA may correspond to a non-display area NDA shown in FIG. 1.

Signal lines GL1 to GLn and DL1 to DLm may include multiple gate lines GL1 to GLn and multiple data lines DL1 to DLm. Each of the pixels PX11 to PXnm may be electrically connected with a corresponding gate line among multiple gate lines GL1 to GLn and a corresponding data line among multiple data lines DL1 to DLm.

Each of the pixels PX11 to PXnm may include a pixel driving circuit and a light emitting element ED (FIG. 5A and FIG. 5B). According to the configuration of the pixel driving circuit of the pixels PX11 to PXnm, more types of signal lines may be provided in the display panel DP. The gate driving circuit GDC may be integrated on the display panel DP through an oxide silicon gate driver circuit (OSG) or amorphous silicon gate driver circuit (ASG) process.

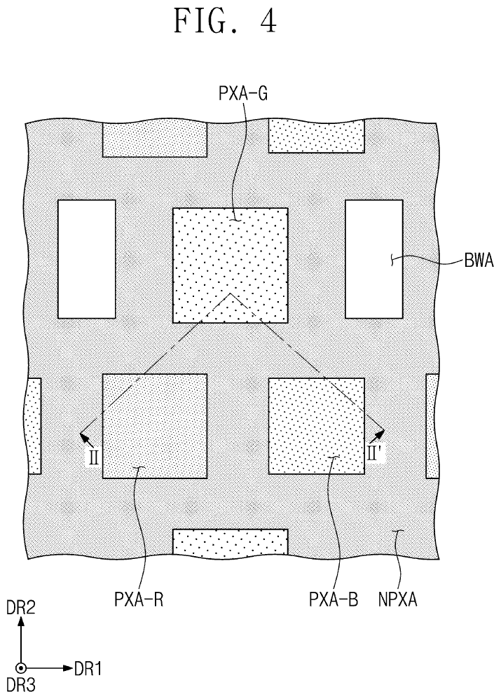

FIG. 4 is an enlarged plan view showing a portion of a display device DD (FIG. 1) according to an embodiment. FIG. 4 is an enlarged plan view of the display area DA in FIG. 1. FIG. 5A is a schematic cross-sectional view showing a portion corresponding to line II-II′ in FIG. 4.

In FIG. 4, a plane including three pixel areas PXA-R, PXA-G and PXA-B, and a bank well area BWA adjacent thereto, is shown as an embodiment. The three pixel areas PXA-R, PXA-G and PXA-B shown in FIG. 4 may be repeatedly disposed throughout the display area DA (FIG. 1).

A light blocking area NPXA may be disposed around the first to third pixel areas PXA-R, PXA-G and PXA-B. The light blocking area NPXA may set the boundaries of the first to third pixel areas PXA-R, PXA-G and PXA-B. The light blocking area NPXA may surround the first to third pixel areas PXA-R, PXA-G and PXA-B. In the light blocking area NPXA, a structure preventing color mixing of the first to third pixel areas PXA-R, PXA-G and PXA-B, for example, a pixel definition film PDL (FIG. 5A and FIG. 5B) or a bank BMP (FIG. 5A and FIG. 5B) may be disposed.

In FIG. 4, the first to third pixel areas PXA-R, PXA-G and PXA-B are shown to have a same shape and have different areas in a plan view, but the disclosure is not limited thereto. At least two pixel areas of the first to third pixel areas PXA-R, PXA-G and PXA-B may have a same area. The areas of the first to third pixel areas PXA-R, PXA-G and PXA-B may be determined depending on the color of light emitted. The area of a pixel area emitting red light among primary colors may be the greatest, and the area of a pixel area emitting blue light may be the smallest.

In FIG. 4, each of the first to third pixel areas PXA-R, PXA-G and PXA-B is shown as having a rectangular shape in a plan view. However, the disclosure is not limited thereto, and in another embodiment, each of the first to third pixel areas PXA-R, PXA-G and PXA-B may have another polygonal shape such as a rhombus and pentagon. In another embodiment, each of the first to third pixel areas PXA-R, PXA-G and PXA-B may have a rectangular shape with rounded corners. In an embodiment, each of the first to third pixel areas PXA-R, PXA-G and PXA-B may have a different shape in a plan view.

In FIG. 4, the second pixel area PXA-G is placed in the first row, and the first pixel area PXA-R and the third pixel area PXA-B are placed in the second row. However, the disclosure is not limited thereto, and the arrangement of the first to third pixel areas PXA-R, PXA-G and PXA-B may be changed in various ways. For example, the first to third pixel areas PXA-R, PXA-G and PXA-B may be arranged in a same row.

One of the first to third pixel areas PXA-R, PXA-G and PXA-B may emit first light, another one may emit second light that is different from the first light, and the other one may emit third light that is different from the first light and the second light. For example, the first pixel area PXA-R may emit red light, the second pixel area PXA-G may emit green light, and the third pixel area PXA-B may emit blue light. The first pixel area PXA-R may be referred to as a red pixel area, the second pixel area PXA-G may be referred to as a green pixel area, and the third pixel area PXA-B may be referred to as a blue pixel area.

In the display area DA (FIG. 1), a bank well area BWA may be defined. The bank well area BWA may be an area formed for preventing defects due to mis-landing in the process of pattering multiple light control parts CCP1, CCP2 and CCP3, included in the light control layer CCL (FIG. 5A and FIG. 5B). The bank well area BWA may be an area from which a portion of the bank BMP (FIG. 5A and FIG. 5B) is removed. FIG. 4 shows that two bank well areas BWA are formed adjacent to the second pixel area PXA-G, but the disclosure is not limited thereto, and the shape and arrangement of the bank well areas BWA may vary diversely. In another embodiment, different from the drawing, the bank well area BWA may be omitted.

Referring to FIG. 5A, the base substrate BS may include a single layer or multiple layers. For example, the base substrate BS may include a three-layer structure of a polymer resin layer, an adhesive layer and a polymer resin layer. For example, the polymer resin layer may be a polyimide-based resin. In another embodiment, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin and a perylene-based resin. In the description, “˜˜”-based resin means a resin including a functional group of “˜˜”. For example, a polyimide-based resin may be a resin including a polyimide functional group.

The circuit layer DP-CL may include an insulating layer, a semiconductor layer, a conductive layer and a signal line. The circuit layer DP-CL may include multiple transistors (not shown). Each of the transistors (not shown) may include a control electrode, an input electrode, and an output electrode. For example, the circuit layer DP-CL may include a switching transistor and a driving transistor for driving the light emitting element ED of the display element layer DP-ED.

The display element layer DP-ED may include a light emitting element ED and a pixel definition film PDL. The pixel definition film PDL may include an opening OH. In an embodiment, the display element layer DP-ED may include an encapsulation layer TFE disposed on the light emitting element ED.

The light emitting element ED may include an organic light emitting element and/or an inorganic light emitting element. In another embodiment, the display element layer DP-ED may include an ultra-small light emitting element. For example, the ultra-small light emitting element may include a micro LED element and/or a nano LED element. The ultra-small light emitting element may be a light emitting element having a micro- or nano-scale size and including an active layer disposed between multiple semiconductor layers.

The light emitting element ED may include a first electrode EL1, a second electrode EL2 oppositely disposed to the first electrode EL1, and an emission layer EML disposed between the first electrode EL1 and the second electrode EL2. In an embodiment, the light emitting element ED may include a hole transport region HTR disposed between the first electrode EL1 and the emission layer EML, and an electron transport region ETR disposed between the emission layer EML and the second electrode EL2. In the light emitting element ED, the emission layer EML may emit source light. The source light may include blue light and green light. In FIG. 5A, a light emitting element ED including one emission layer EML is shown, but the disclosure is not limited thereto, and the light emitting element ED may include multiple emission layers. For example, the light emitting element ED may be a light emitting element with a tandem structure.

At least a portion of the first electrode EL1 may be exposed by the opening OH of the pixel definition film PDL. The first electrode EL1 may have conductivity. The first electrode EL1 may be formed using a metal material, a metal alloy or a conductive compound. The first electrode EL1 may be a cathode or an anode. However, the disclosure is not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn and Zn, a compound thereof, a mixture thereof, and an oxide thereof.

If the first electrode EL1 is a transmissive electrode, the first electrode EL1 may include a transparent metal oxide, for example, indium tin oxide (ITO), indium zinc oxide (IZO), zinc oxide (ZnO), indium tin zinc oxide (ITZO), or the like. If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (for example, a mixture of Ag and Mg). In an embodiment, the first electrode EL1 may have a structure including multiple layers including a reflective layer or a transflective layer formed using the above materials, and a transmissive conductive layer formed using ITO, IZO, ZnO, or ITZO. For example, the first electrode EL1 may have a three-layer structure of ITO/Ag/ITO, but the disclosure is not limited thereto. In an embodiment, the first electrode EL1 may include the above-described metal material, a combination of the above-described metal materials, or an oxide of the above-described metal materials. However, the disclosure is not limited thereto.

The hole transport region HTR may have a layer formed using a material, a layer formed using different materials, or a structure including layers formed using different materials. The hole transport region HTR may include a hole injection material and/or a hole transport material. The hole transport region HTR may include at least one of a hole injection layer, a hole transport layer, and an electron blocking layer.

The emission layer EML may emit source light including blue light and green light. The emission layer EML may include an organic light emitting material and/or an inorganic light emitting material. For example, the emission layer EML may include a fluorescence emitting material and/or a phosphorescence emitting material. In another embodiment, the emission layer EML may include quantum dots as a light emitting material.

The electron transport region ETR may have a layer formed using a material, a layer formed using different materials, or a structure including layers formed using different materials. The electron transport region ETR may include an electron injection material and/or an electron transport material. The electron transport region ETR may include at least one of an electron injection layer, an electron transport layer, and a hole blocking layer.

In FIG. 5A, the hole transport region HTR, the emission layer EML and the electron transport region ETR are provided as common layers, but the disclosure is not limited thereto. For example, the hole transport region HTR, the emission layer EML and/or the electron transport region ETR may be patterned and provided in the opening OH defined in the pixel definition film PDL.

The second electrode EL2 may be a common electrode. The second electrode EL2 may be an anode or a cathode, but the disclosure is not limited thereto. For example, if the first electrode EL1 is an anode, the second electrode EL2 may be a cathode, and if the first electrode EL1 is a cathode, the second electrode EL2 may be an anode. The second electrode EL2 may include at least one of Ag, Mg, Cu, Al, Pt, Pd, Au, Ni, Nd, Ir, Cr, Li, Ca, LiF, Mo, Ti, W, In, Sn, and Zn, a compound thereof, a mixture thereof, and an oxide thereof.

The second electrode EL2 may be a transmissive electrode, a transflective electrode or a reflective electrode. If the second electrode EL2 is a transmissive electrode, the second electrode EL2 may include a transparent metal oxide, for example, ITO, IZO, ZnO, ITZO, etc.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (for example, AgMg, AgYb, or MgYb). In another embodiment, the second electrode EL2 may have a multilayered structure including a reflective layer or a transflective layer formed using the above-described material and a transparent conductive layer formed using ITO, IZO, ZnO, ITZO, etc. For example, the second electrode EL2 may include the aforementioned metal materials, a combination of the aforementioned metal materials, or an oxide of the aforementioned metal materials.

Though not shown, an element capping layer may be provided on the second electrode EL2. The element capping layer (not shown) may be a single layer or multiple layers. The element capping layer (not shown) may include at least one of an alkali metal compound such as LiF, an alkaline earth metal compound such as MgF2, and an inorganic material such as SiON, SiNₓ, and SiO_{y}. In another embodiment, the element capping layer (not shown) may include α-NPD, NPB, TPD, m-MTDATA, Alq3, CuPc, N4,N4,N4′,N4′-tetra(biphenyl-4-yl) biphenyl-4,4′-diamine (TPD15), 4,4′,4″-tris(carbazol-9-yl) triphenylamine (TCTA), or the like, or may include an organic material such as an epoxy resin and an acrylate such as methacrylate.

The pixel definition film PDL may be formed using a polymer resin. For example, the pixel definition film PDL may include a polyacrylate-based resin or a polyimide-based resin. In another embodiment, the pixel definition film PDL may include an inorganic material in addition to the polymer resin. In an embodiment, the pixel definition film PDL may include a light absorption material or a black pigment or a black dye. The pixel definition film PDL including a black pigment or a black dye may be a black pixel definition film. Carbon black, or the like may be used as the black pigment or the black dye during forming the pixel definition film PDL, but the disclosure is not limited thereto.

In another embodiment, the pixel definition film PDL may include an inorganic material. For example, the pixel definition film PDL may include an inorganic material such as silicon nitride (SiNₓ), silicon oxide (SiOₓ), silicon oxynitride (SiOₓN_{y}) or the like.

First to third light emitting areas EA1, EA2 and EA3 may be defined by the opening OH of the pixel definition film PDL.

The first light emitting area EA1, the second light emitting area EA2 and the third light emitting area EA3 may be areas divided by the pixel definition film PDL. The first light emitting area EA1, the second light emitting area EA2 and the third light emitting area EA3 may correspond to the first pixel area PXA-R, the second pixel area PXA-G and the third pixel area PXA-B, respectively. The light emitting areas EA1, EA2 and EA3 may overlap the pixel areas PXA-R, PXA-G and PXA-B, and may not overlap the bank well area BWA (FIG. 4) in a plan view. In a plan view, the areas of the light emitting areas EA1, EA2 and EA3 may be smaller than the areas of the pixel areas PXA-R, PXA-G and PXA-B. In this description, the fact that a certain component corresponds to another component is not limited to a case where the certain component and the other component have a same area and a same shape, but includes a case where the certain component and the other component have different areas and/or different shapes.

The display element layer DP-ED may include an encapsulation layer TFE disposed on the second electrode EL2. The encapsulation layer TFE may cover the light emitting element ED. The encapsulation layer TFE may be a thin film encapsulation layer. The encapsulation layer TFE may include one layer or a stack of multiple layers. The encapsulation layer TFE may include at least one insulating layer. The encapsulation layer TFE may include at least one inorganic film (hereinafter referred to as encapsulation inorganic film). In an embodiment, the encapsulation layer TFE may include at least one organic film (hereinafter referred to as encapsulation organic film) and at least one encapsulation inorganic film.

The encapsulation inorganic film may protect the light emitting element ED from moisture/oxygen, and the encapsulation organic film may protect the light emitting element ED from foreign materials such as dust particles. The encapsulation inorganic film may include silicon nitride, silicon oxynitride, silicon oxide, titanium oxide, or aluminum oxide, but the disclosure is not limited thereto. The encapsulation organic film may include an acrylic compound, an epoxy-based compound, or the like. The encapsulation organic film may include a photopolymerizable organic material, but the disclosure is not limited thereto.

A display device DD may further include a filling layer FML disposed between a display panel DP and an optical panel OPN. The filling layer FML may charge between the display panel DP and the optical panel OPN. The filling layer FML may function as a buffer. The filling layer FML may function as an impact absorber and increase the strength of the display device DD. The filling layer FML may be formed from a filling resin containing a polymer resin. For example, the filling layer FML may be formed from a filling resin containing an acrylic resin, an epoxy resin, or the like. In another embodiment, the filling layer FML may be omitted.

The optical panel OPN may include a color control member CCM and a base layer BL. The base layer BL may be a member providing a base surface for disposing the color control member CCM. The base layer BL may be a glass substrate, a metal substrate, a plastic substrate or the like. However, the disclosure is not limited thereto, and the base layer BL may be an inorganic layer, an organic layer or a composite material layer. In another embodiment, the base layer BL may be omitted from the display device DD. Though not shown, a functional layer such as an antistatic layer, an anti-fingerprint layer, and a hard coating layer may be further disposed on the base layer BL.

The light control member CCM may include a light control layer CCL disposed on the display element layer DP-ED, a color filter layer CFL disposed on the light control layer CCL, and a low refractive index layer LR disposed between the light control layer CCL and the color filter layer CFL. The light control layer CCL may include first to third light control parts CCP1, CCP2 and CCP3, and a bank BMP.

The first light control part CCP1 may be provided to correspond to the first pixel area PXA-R, the second light control part CCP2 may be provided to correspond to the second pixel area PXA-G, and the third light control part CCP3 may be provided to correspond to the third pixel area PXA-B. In a direction perpendicular to a thickness direction DR3, the first to third light control parts CCP1, CCP2 and CCP3 may be separated from each other. The bank BMP may be disposed between the light control parts CCP1, CCP2 and CCP3, separated from each other. However, the disclosure is not limited thereto, and at least a portion of the edges of the light control parts CCP1, CCP2 and CCP3 may overlap the bank BMP in the thickness direction DR3.

The bank BMP may include a base resin and an additive. The base resin may be composed of a resin composition that may be generally referred to as a binder. The additive may include a coupling agent and/or a photoinitiator. The additive may further include a dispersant.

The bank BMP may include a black coloring agent for blocking light. The bank BMP may include a black dye and/or a black pigment mixed in the base resin. The black coloring agent may include carbon black, or may include a metal such as chromium or an oxide thereof.

The first light control part CCP1 may include first quantum dots QD1, and the first quantum dots QD1 may convert source light provided from the display element layer DP-ED into first light. The first quantum dots QD1 may emit light in a wavelength range of about 630 nm to about 750 nm. The first light may be red light. The first quantum dots QD1 may be red quantum dots. The weight of the first quantum dots QD1 may be in a range of about 10 wt % to about 50 wt % on the basis of about 100 wt % of the total weight of the first light control part CCP1. If the first quantum dots are provided in less than about 10 wt % or greater than about 50 wt % on the basis of about 100 wt % of the total weight of the first light control part CCP1, light conversion degree may be insufficient, or the amount of light absorbed may be greater than the amount of light emitted to degrade display quality. However, the display device DD of an embodiment, which includes about 10 wt % to about 50 wt % of the first quantum dots QD1 on the basis of about 100 wt % of the total weight of the first light control part CCP1 may show excellent display quality.

The third light control part CCP3 may transmit the source light provided from the display element layer DP-ED. The third light control part CCP3 may not include quantum dots.

The second light control part CCP2 may include second quantum dots QD2 and a metal nanomaterial NP, and may convert the source light provided from the display element layer DP-ED into second light. The second light control part CCP2 may further include a scatterer SP.

The second quantum dots QD2 may emit light in a wavelength in a range of about 495 nm to about 570 nm. The second light may include green light. In an embodiment, the second light may further include yellow light and/or orange light. The second quantum dots QD2 may be green quantum dots.

The scatterer SP may be a material that scatters light and may increase the light conversion efficiency of the second quantum dots QD2. However, since the scatterer SP may also scatter light introduced into the second light control part CCP2 from the outside of the display device DD, the reflectance of a Specular Component Excluded (SCE) may be increased and deteriorate the display quality of the display device DD.

In an embodiment, the metal nanomaterial NP may absorb light in a wavelength range of about 550 nm to about 590 nm. The metal nanomaterial NP may have an absorption peak wavelength with absolute maximum light absorption in a wavelength range greater than a wavelength variation region (wavelength range of about 520 nm to about 540 nm), which will be described below. The metal nanomaterial NP may have an absorption peak wavelength in a range of about 550 nm to about 590 nm. According to a relative visibility curve, light in the wavelength range of about 550 nm to about 590 nm may correspond to light that has high influence on reflectance, which deteriorates the display quality of the display device. The human eye has the maximum visibility to light with a wavelength of about 555 nm, and with the maximum visibility set to 1, the ratio of the visibility to light of different wavelengths (about 380 nm to about 760 nm) is referred to as relative visibility, and a curve represented by the relative visibility is a relative visibility curve.

In the display device DD of an embodiment, the reflectance may be reduced by including a metal nanomaterial NP that absorbs light in a wavelength range of about 550 nm to about 590 nm in the second light control part CCP2 including green quantum dots QD2. As light with high influence on reflectance is absorbed, the display device DD of an embodiment may have reduced reflectance and exhibit excellent display quality.

The absorption spectrum of the metal nanomaterial NP may include a wavelength variation region in a wavelength range of about 520 nm to about 540 nm. The wavelength variation region may be a region where absorbance decreases and increases and has a downward concave shape, and may include a valley. The wavelength range of about 520 nm to about 540 nm may be a range containing the wavelength at which green light emitted from the second filter CF2, which will be explained below, has the absolute maximum light emitting intensity. As the absorbance of the metal nanomaterial NP decreases in a wavelength range of about 520 nm to about 540 nm, absorption of green light emitted from the second filter CF2 into the metal nanomaterial NP may be minimized. Accordingly, the metal nanomaterial NP having the wavelength variation region in a wavelength range of about 520 nm to about 540 nm may reduce reflectance that deteriorates display quality, while maintaining the light efficiency of the display device DD.

In an embodiment, the metal nanomaterial NP may include at least one of yellow quantum dots, orange quantum dots, and a material in which surface plasmon resonance occurs. The metal nanomaterial NP may include at least one of yellow quantum dots, orange quantum dots, gold nanoparticles, silver nanoparticles, and silver nanoplates. The gold nanoparticles, silver nanoparticles, and silver nanoplates may be materials in which surface plasmon resonance phenomenon occurs. The gold nanoparticles, silver nanoparticles, and silver nanoplates may absorb light in a wavelength range of about 550 nm to about 590 nm by the surface plasmon resonance phenomenon.

The metal nanomaterial NP including the yellow quantum dots and/or orange quantum dots may emit light in a wavelength range of about 550 nm to about 630 nm. The metal nanomaterial NP including the yellow quantum dots and/or orange quantum dots may have a light emitting central wavelength in a wavelength range of about 580 nm to about 630 nm. The light emitting central wavelength may be a wavelength at which the luminous intensity is absolute maximum in an emission spectrum. In a wavelength range between about 550 nm and about 630 nm, the short wavelength range may correspond to green light, and the metal nanomaterial NP that emits light in a wavelength range between about 550 nm and about 630 nm may improve the light efficiency of the display device DD.

In the emission spectrum of the second light control part CCP2 including the metal nanomaterial NP including yellow quantum dots and/or orange quantum dots, multiple peak wavelengths may be observed. In the emission spectrum, the peak wavelength may be a wavelength at a point where the luminous intensity is a local maximum value. For example, in the emission spectrum of the second light control part CCP2 including yellow quantum dots and/or orange quantum dots, a peak wavelengths may be observed in each of the wavelength range of about 520 nm and about 540 nm and the wavelength range of about 580 nm and about 630 nm. The second light control part CCP2 may have an absolute maximum luminous intensity in a wavelength range of about 520 nm and about 540 nm.

A diameter of each of the gold nanoparticles, silver nanoparticles, and silver nanoplates may be in a range of about 10 nm to about 800 nm. For example, the diameter of each of the gold nanoparticles and silver nanoparticles may be in a range of about 60 nm to about 150 nm. The diameter of the silver nanoplates may be in a range of about 500 nm and about 700 nm.

If multiple gold nanoparticles are provided, the median diameter (D50) of the multiple gold nanoparticles may in a range of be about 10 nm to about 800 nm. If multiple silver nanoparticles are provided, the median diameter (D50) of the multiple silver nanoparticles may be in a range of about 10 nm to about 800 nm. If multiple silver nanoplates are provided, the median diameter (D50) of the multiple silver nanoplates may be in a range of about 10 nm to about 800 nm. For example, the median diameters (D50) of the multiple gold nanoparticles and multiple silver nanoparticles may be in a range of about 60 nm to about 150 nm. The median diameter (D50) of the multiple silver nanoplates may be in a range of about 500 nm to about 700 nm. The median diameter (D50) may be a middle value of the diameter.

In an embodiment, the weight of the metal nanomaterial NP may be in a range of about 0.1 wt % to about 15 wt % on the basis of about 100 wt % of the total weight of the second light control part CCP2. If the metal nanomaterial is provided in less than about 0.1 wt % on the basis of about 100 wt % of the total weight of the second light control part CCP2, the display device may not show reflectance reduction effect. If the metal nanomaterial is provided in greater than about 15 wt % on the basis of about 100 wt % of the total weight of the second light control part CCP2, the amount of light absorbed may become greater than the amount of light emitted, and light efficiency may be deteriorated. However, in an embodiment, if the metal nanomaterial NP is in a range of about 0.1 wt % to about 15 wt % on the basis of about 100 wt % of the total weight of the second light control part CCP2, the metal nanomaterial NP may reduce reflectance and improve the display quality of the display device DD, while maintaining excellent light efficiency.

The weight of the second quantum dots QD2 may be in a range of about 10 wt % to about 50 wt % on the basis of about 100 wt % of the total weight of the second light control part CCP2. If the second quantum dots are provided in less than about 10 wt % on the basis of about 100 wt % of the total weight of the second light control part CCP2, the light conversion degree may be insufficient, and the light efficiency and the display quality may be degraded. If the second quantum dots are provided in greater than about 50 wt % on the basis of about 100 wt % of the total weight of the second light control part CCP2, the amount of light absorbed may become greater than the amount of light emitted in the light control layer, and the light efficiency may be deteriorated. As the weight of the metal nanomaterial other than the second quantum dots in the second light control unit decreases, the effect of reducing reflectance may not appear. However, in an embodiment, if the second quantum dots are in a range of about 10 wt % to about 50 wt % on the basis of about 100 wt % of the total weight of the second light control part CCP2, the reflectance may decrease, while maintaining excellent light efficiency, and the display device DD may show excellent display quality.

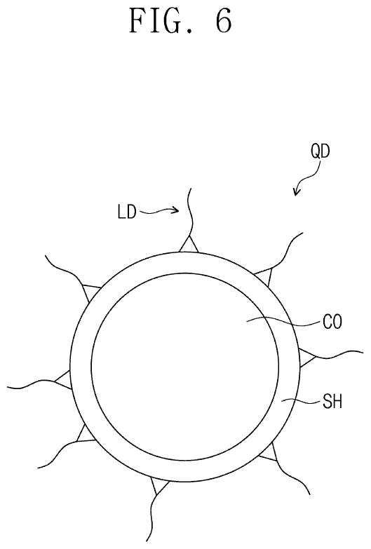

FIG. 6 is a schematic diagram showing a quantum dot QD according to an embodiment. In FIG. 6, the quantum dot QD may correspond to the above-described first quantum dot QD1, second quantum dot QD2, yellow quantum dot, and orange quantum dot.

In the description, the quantum dot QD may be a crystal of a semiconductor compound. The quantum dot QD may emit light of various wavelengths by changing the size of a crystal and/or the element ratio in the compound. The quantum dot QD may be synthesized by a chemical bath deposition, a metal organic chemical vapor deposition, a molecular beam epitaxy or a similar process therewith. The chemical bath deposition is a method of growing quantum dot QD particle crystal after mixing an organic solvent and a precursor material. During the growth of the crystal, the organic solvent may naturally play the role of a dispersant coordinated at the surface of the quantum dot QD crystal and may control the growth of the crystal, and accordingly, the chemical bath deposition may be more favorable than a vapor deposition method such as a metal organic chemical vapor deposition (MOCVD) and a molecular beam epitaxy (MBE), and may control the growth of the quantum dot QD particle through a low cost process.

Referring to FIG. 6, the quantum dot QD may include a core CO and a shell SH surrounding the core CO. In an embodiment, the quantum dot QD may further include a ligand LD bonded to the surface of the shell SH. The ligand LD may include a ligand material. The ligand LD may eliminate defects in the core CO and/or shell SH and increase the stability of the quantum dot QD. In another embodiment, the quantum dot QD may have a single structure in which the concentration of each element contained in the quantum dot QD is uniform.

The core CO may include a II-VI group semiconductor compound, a I-II-VI group semiconductor compound, a II-IV-VI group compound, a I-II-IV-VI group semiconductor compound, a III-V group semiconductor compound, a III-II-V group semiconductor compound, a III-VI group semiconductor compound, a I-III-VI group semiconductor compound, a IV-VI group semiconductor compound, a II-IV-V group semiconductor compound, a IV group semiconductor compound, a IV group element, a mixture thereof, or a compound thereof. In the description, the “group” means the group in an IUPAC periodic table.

Examples of the II-VI group compound may include: a binary compound such as CdS, CdSe, CdTe, ZnS, ZnSe, ZnTe, ZnO, HgS, HgSe, HgTe, MgSe, and MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS; a quaternary compound such as CdZnSeS, CdZnSeTe, CdZnSTe, CdHgSeS, CdHgSeTe, CdHgSTe, HgZnSeS, HgZnSeTe, and HgZnSTe; or a combination thereof.

The II-VI group semiconductor compound may further include a metal in group I and/or an element in group IV. The I-II-VI group compound may include CuSnS or CuZnS, and the II-IV-VI group compound may include ZnSnS, etc. The I-II-IV-VI group compound may include a quaternary compound such as Cu₂ZnSnS₂, Cu₂ZnSnS₄, Cu₂ZnSnSe₄, Ag₂ZnSnS₂, and a mixture thereof.

Examples of the III-V group semiconductor compound may include: a binary compound such as GaN, GaP, GaAs, GaSb, AlN, AlP, AlAs, AlSb, InN, InP, InAs, and InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; or a combinations thereof. The III-V group semiconductor compound may further include a II group element. Examples of the III-V group semiconductor compound including the element in group II may include InZnP, InGaZnP, InAlZnP, etc.

Examples of the III-VI group semiconductor compound may include: a binary compound such as GaS, Ga₂S₃, GaSe, Ga₂Se₃, GaTe, InS, InSe, In₂Se₃, and InTe; a ternary compound such as InGaS₃, and InGaSe₃; or a combination thereof.

Examples of the I-III-VI group semiconductor compound may include: a ternary compound such as AgInS, AgInS₂, AgInSe₂, AgGaS, AgGaS₂, AgGaSe₂, CuInS, CuInS, CuInSe, CuGaS, CuGaSe, CuGaO₂, AgGaO₂, and AgAlO₂; a quaternary compound such as AgInGaS₂, AgInGaSe₂, CuGaSeS, CuInGaS, and CuInGaSe; a quinary compound such as CuInGaSeS; or a combinations thereof.

Examples of the IV-VI group semiconductor compound may include: a binary compound such as SnS, SnSe, SnTe, PbS, PbSe, and PbTe; a ternary compound such as SnSeS, SnSeTe, SnSTe, PbSeS, PbSeTe, PbSTe, SnPbS, SnPbSe, and SnPbTe; a quaternary compound such as SnPbSSe, SnPbSeTe, and SnPbSTe; or a combinations thereof.

Examples of the II-IV-V group semiconductor compound may include a ternary compound such as ZnSnP, ZnSnP₂, ZnSnAs₂, ZnGeP₂, ZnGeAs₂, CdSnP₂, CdGeP₂ and a mixture thereof.

The IV group element or compound may include: a single element compound such as Si, and Ge; a binary compound such as SiC, and SiGe; or a combination thereof.

Each element included in a polynary compound such as a binary compound, a ternary compound and a quaternary compound may be present at uniform concentration or non-uniform concentration in a particle. For example, the chemical formulae may indicate the types of elements included in the compound, and the element ratio in the compound may be different. For example, AgInxGa₁₋ₓS₂ (x is a real number of 0 to 1) may include AgInGaS₂.

For example, each of the yellow quantum dots and orange quantum dots included in the metal nanomaterial NP (FIG. 5A) may include at least one of CuInS₂, CuInSe₂, CuInSeS, CuGaS₂, CuGaSe₂, CuGaSeS, CuInGaS₂, CuInGaSe₂, CuInGaSeS, and InP. However, the disclosure is not limited thereto.

In the quantum dot QD, the material included in the core CO and the material included in the shell SH may be different. The shell may play the role of a protection layer for preventing the chemical deformation of the core CO and maintaining semiconductor properties and/or a charging layer for providing the quantum dot with electrophoresis properties. The shell SH may be a single layer or a multilayer. In the quantum dot QD, the shell SH may have a concentration gradient in which the concentration of an element presents in the shell decreases toward the core CO.

In an embodiment, the shell SH may include a metal oxide, a non-metal oxide, a semiconductor compound, or a combination thereof. Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄ and NiO; a ternary compound such as MgAl₂O₄, CoFe₂O₄, NiFe₂O₄ and CoMn₂O₄; or a combination thereof. Examples of the semiconductor compound may include a III-VI group semiconductor compound, a II-VI group semiconductor compound, a III-V group semiconductor compound, a III-VI group semiconductor compound, a I-III-VI group semiconductor compound, a IV-VI group semiconductor compound, or a combination thereof, as described in this description. For example, the semiconductor compound may include CdS, CdSe, CdSeS, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, etc., or a combination thereof.

Each element included in a polynary compound such as a binary compound, and a ternary compound may be present at uniform concentration or non-uniform concentration in a particle. For example, the chemical formulae may indicate the types of elements included in the compound, and the element ratio in the compound may be different.

The quantum dot QD may have a full width of half maximum (FWHM) less than or equal to about 45 nm in an emission spectrum. For example, the quantum dot QD may have a full width of half maximum (FWHM) less than or equal to about 40 nm in the emission spectrum. For example, the quantum dot QD may have a full width of half maximum (FWHM) less than or equal to or about 30 nm in the emission spectrum. Within this range, color purity or color reproducibility may be improved. Light emitted via such quantum dot QD may be emitted in all directions, and light view angle may be improved. The shape of the quantum dot QD may be spherical, pyramidal, multi-arm, cubic nanoparticle, nanotube, nanowire, nanofiber, nanoplate particle, etc.

By controlling the size of the quantum dot QD or by controlling the element ratio in the compound constituting the quantum dot QD, an energy band gap may be controlled, and light in various wavelength bands may be obtained from a light control layer CCL including the quantum dot QD.

Referring to FIG. 5A again, each of the first to third light control parts CCP1, CCP2 and CCP3 may further include a scatterer SP. The weight of the scatterer SP may be in a range of about 0 wt % to about 15 wt % on the basis of about 100 wt % of the total weight of the second light control part CCP2. If the scatterer is provided in greater than about 15 wt % on the basis of about 100 wt % of the total weight of the second light control part CCP2, the reflectance may increase rather than light conversion efficiency, and the display quality of the display device may be degraded. However, in an embodiment, a display device DD including the scatterer in a range of about 0 wt % to about 15 wt % on the basis of about 100 wt % of the total weight of the second light control part CCP2 may have reduced reflectance, while maintaining excellent light conversion efficiency. Accordingly, the display device DD of an embodiment may have excellent display quality.

The weight of the scatterer SP may be in a range of about 0 wt % to about 15 wt % on the basis of about 100 wt % of the total weight of the first light control part CCP1. In an embodiment, a display device DD including the scatterer in a range of about 0 wt % to about 15 wt % on the basis of about 100 wt % of the total weight of the first light control part CCP1 may have excellent display quality.

For example, the weight of the scatterer SP may be in a range of about 0 wt % to about 15 wt % on the basis of about 100 wt % of the total weight of the third light control part CCP3. However, the weight of the scatterer SP included in the third light control part CCP3 is not limited thereto.

The scatterer SP may be inorganic particles. For example, the scatterer SP may include at least one of TiO₂, SiO₂, BaTiO₃, BaO, ZnS, ZnO, Al₂O₃, hollow silica, and a mixture thereof.

For example, multiple scatterers SP may be provided. The median diameter (D50) of the scatterers SP may be in a range of about 50 nm to about 500 nm. The scatterers SP having the median diameter (D50) in a range of about 50 nm to about 500 nm may improve light conversion efficiency in the first and second light control parts CCP1 and CCP2.

Each of the first light control part CCP1, the second light control part CCP2 and the third light control part CCP3 may include base resins BR1, BR2 and BR3. The first light control part CCP1 may include first quantum dots QD1 and the scatterer SP, dispersed in the first base resin BR1. The second light control part CCP2 may include second quantum dots QD2, a metal nanomaterial NP, and the scatterer SP, dispersed in the second base resin BR2. The third light control part CCP3 may include the scatterer SP dispersed in the third base resin BR3.

The base resins BR1, BR2 and BR3 may be mediums in which the first quantum dots QD1, the second quantum dots QD2, the metal nanomaterial NP, and the scatterer SP are dispersed, and may be composed of a resin composition that may be generally referred to as binders. For example, the base resins BR1, BR2 and BR3 may be an acrylic resin, a urethane-based resin, a silicon-based resin, an epoxy-based resin or the like. The base resins BR1, BR2 and BR3 may be transparent resins. The first base resin BR1, the second base resin BR2 and the third base resin BR3 may be the same, or at least one the first base resin BR1, the second base resin BR2 and the third base resin BR3 may be different.

A low refractive index layer LR may be disposed on the light control layer CCL and may block the light control parts CCP1, CCP2 and CCP3 from being exposed to humidity and/or oxygen. In an embodiment, the low refractive index layer LR may be disposed between the light control parts CCP1, CCP2 and CCP3, and filters CF1, CF2 and CF3, and may function as an optical functional layer improving light extraction efficiency or preventing the incidence of reflected light to the light control layer CCL. The low refractive index layer LR may be a layer having a small refractive index compared to an adjacent layer.

The low refractive index layer LR may include at least one inorganic layer. For example, the low refractive index layer LR may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. However, the disclosure is not limited thereto, and the low refractive index layer LR may include an organic film. The low refractive index layer LR may have, for example, a structure in which multiple hollow particles are dispersed in an organic polymer resin. The low refractive index layer LR may be composed of a single layer or multiple layers.

In an embodiment, a first barrier layer BFL1 may be provided between the encapsulation layer TFE and the light control layer CCL. The first barrier layer BFL1 may play the role of preventing the penetration of humidity and/or oxygen. The first barrier layer BFL1 may prevent the light control parts CCP1, CCP2 and CCP3 from being exposed to humidity and/or oxygen. The first barrier layer BFL1 may cover the first to third light control parts CCP1, CCP2 and CCP3. Between the light control layer CCL and the low refractive index layer LR, a second barrier layer BFL2 may be provided. In another embodiment, at least one of the first and second barrier layers BFL1 and BFL2 may be omitted.

Each of the first and second barrier layers BFL1 and BFL2 may include at least one inorganic layer. For example, each of the first and second barrier layers BFL1 and BFL2 may include an inorganic material. For example, each of the first and second barrier layers BFL1 and BFL2 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film securing light transmittance. Each of the first and second barrier layers BFL1 and BFL2 may further include an organic film. Each of the first and second barrier layers BFL1 and BFL2 may be composed of a single layer or multiple layers.

A color filter layer CFL may include first to third filters CF1, CF2 and CF3. Each of the first to third filters CF1, CF2 and CF3 may be disposed to correspond to the first to third light control parts CCP1, CCP2 and CCP3 of the light control layer CCL. The first filter CF1 may transmit first light, the second filter CF2 may transmit second light, and the third filter CF3 may transmit source light. For example, the first filter CF1 may be a red filter, the second filter CF2 may be a green filter, and the third filter CF3 may be a blue filter. Each of the first to third filters CF1, CF2 and CF3 may be disposed to correspond to the first to third pixel areas PXA-R, PXA-G and PXA-B. For example, at least a portion of the first to third filters CF1, CF2 and CF3 may be disposed in a light blocking area NPXA.

Each of the first to third filters CF1, CF2 and CF3 may include a polymer photosensitive resin, and a pigment or dye. The first filter CF1 may include a red pigment or a red dye, the second filter CF2 may include a green pigment or a green dye, and the third filter CF3 may include a blue pigment or a blue dye. However, the disclosure is not limited thereto, and the third filter CF3 may not include a pigment or dye. The third filter CF3 may include a polymer photosensitive resin and may not include a pigment or a dye. The third filter CF3 may be transparent. The third filter CF3 may be formed of a transparent photosensitive resin.

In an embodiment, the first filter CF1 and the second filter CF2 may be yellow filters. The first filter CF1 and the second filter CF2 may not be distinguished from each other and provided as one unit.

Though not shown, the color filter layer CFL may further include a light blocking part (not shown). The light blocking part may be black matrix. The light blocking part may include an organic light blocking material or an inorganic light blocking material, and a black pigment or a black dye. The light blocking part may prevent light leakage phenomenon and divide the boundaries between adjacent filters CF1, CF2 and CF3.

FIG. 5B is a schematic cross-sectional view showing a display device DD according to another embodiment of the disclosure. In the explanation on FIG. 5B, contents that overlap those described with reference to FIG. 1 to FIG. 5A will not be described again, and the difference will be explained.

Compared to FIG. 5A, FIG. 5B shows a difference in an emission layer EML-a. Different from the emission layer EML shown in FIG. 5A, the emission layer EML-a shown in FIG. 5B may be patterned and provided in the opening OH of a pixel definition film PDL. At least one of the emission layers EML-a, respectively corresponding to the first to third pixel areas PXA-R, PXA-G and PXA-R may emit light in a different wavelength range. In another embodiment, the emission layers EML-a, respectively corresponding to the first to third pixel areas PXA-R, PXA-G and PXA-R may emit light in a same wavelength range.

Hereinafter, a display device including a metal nanomaterial and a light control part according to an embodiment of the disclosure will be explained in detail with reference to Examples and a Comparative Example. The examples shown below are illustrations to assist understanding of the disclosure, and the scope of the disclosure is not limited thereto.

### Examples

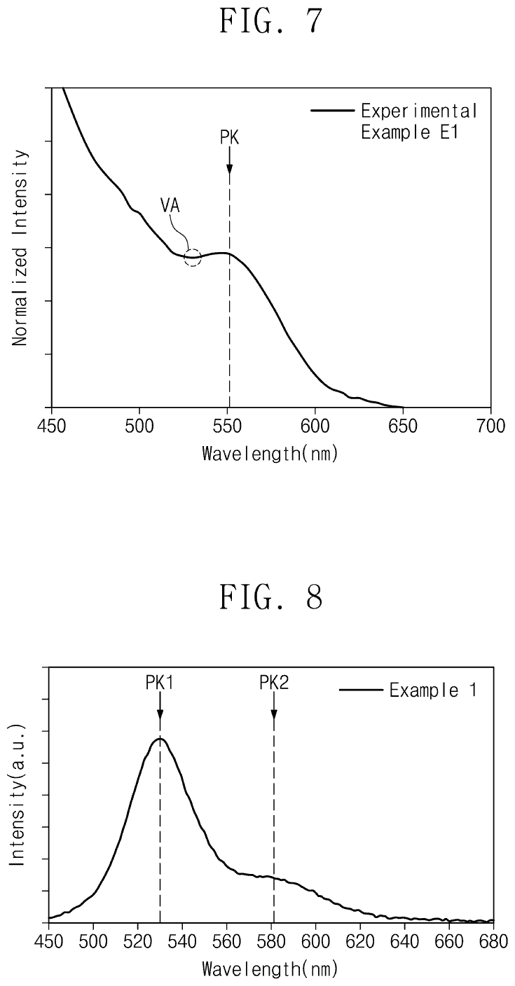

FIG. 7 is a graph showing absorbance in accordance with wavelength in Experimental Example E1, and the absorbance has normalized intensity. In Experimental Example E1, orange quantum dots including InP was used as the metal nanomaterial according to an embodiment. The absorbance in FIG. 7 was measured using QE-2100 (product of Otsuka Electronics Co., Ltd).

Referring to FIG. 7, it can be confirmed that a wavelength variation region VA is included in a wavelength range of about 520 nm to about 540 nm in Experimental Example E1. It can be confirmed that Experimental Example E1 has an absorption peak wavelength PK in a wavelength range greater than the wavelength variation region VA, and the absorption peak wavelength PK is in a range of about 550 nm to about 590 nm.

Hereinafter, orange quantum dots explained in FIG. 8 to FIG. 10 are the orange quantum dots in FIG. 7. FIG. 8 is an emission spectrum and a graph showing luminous intensity in accordance with wavelength. In FIG. 8, the luminous intensity is represented as a relative value (a.u.: arbitrary unit). Example 1 is a display device including a second light control part according to an embodiment, and the second light control part includes green quantum dots and orange quantum dots, where each of the green quantum dots and the orange quantum dots include InP. In Example 1, the weight of the green quantum dots is about 38.4 wt %, and the weight of the orange quantum dots is about 1.6 wt % on the basis of about 100 wt % of the total weight of the second light control part. For example, Example 1 includes the metal nanomaterial according to an embodiment and satisfies the weight range of the green quantum dots (i.e., about 10 wt % to about 50 wt %) and the weight range of the metal nanomaterial (i.e., about 0.1 wt % to about 15 wt %) according to an embodiment. The emission spectrum in FIG. 8 was measured using QE-2100 (product of Otsuka Electronics Co., Ltd).

Referring to FIG. 8, it can be found that multiple peak wavelengths PK1 and PK2 are present in the emission spectrum. It can be found that the peak wavelength with the absolute maximum luminous intensity PK1 is included in a wavelength range of about 520 nm to about 540 nm. It can be also found that the peak wavelength showing the local maximum value of luminous intensity PK2 is included in a wavelength range of about 580 nm to about 630 nm.

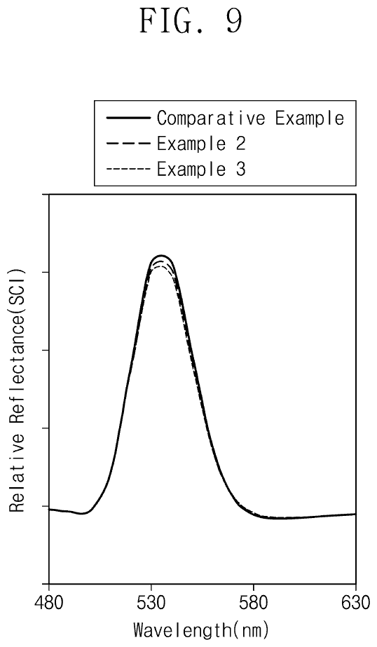

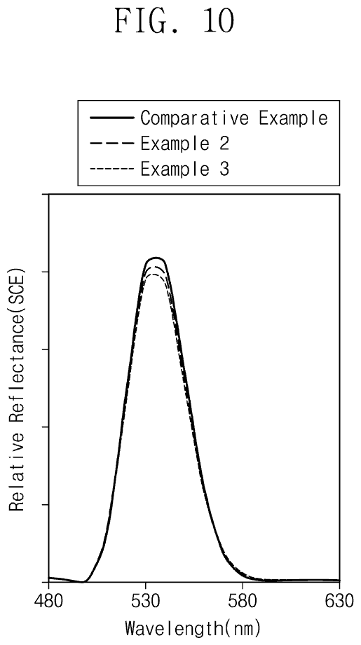

FIG. 9 and FIG. 10 are graphs showing relative reflectance in accordance with wavelength in the display devices of the Comparative Example and the Examples. FIG. 9 is a graph showing relative reflectance for Specular Component Included (SCI), and FIG. 10 is a graph showing relative reflectance for Specular Component Excluded (SCE). The relative reflectance of FIG. 9 and FIG. 10 were measured using CM-3700A (product of KONICA MINOLTA Inc).

In FIG. 9 and FIG. 10, Examples 2 and 3 are display devices including green quantum dots and orange quantum dots according to embodiments, and each of the green quantum dots and the orange quantum dots include InP. Example 2 includes about 4 wt % of orange quantum dots on the basis of about 100 wt % of the total weight of the second light control part, and Example 3 includes about 8 wt % of orange quantum dots on the basis of about 100 wt % of the total weight of the second light control part. Examples 2 and 3 are the second light control parts including the metal nanomaterial according to an embodiment, and the weight of the metal nanomaterial satisfies the above-described weight range (i.e., about 0.1 wt % to about 15 wt %). In FIG. 9 and FIG. 10, the Comparative Example is a light control part including green quantum dots but not including the metal nanomaterial. In FIG. 9 and FIG. 10, the only difference between Examples 2 and 3 and the Comparative Example is whether or not the metal nanomaterial is included.

Referring to FIG. 9, compared to the light control part of the Comparative Example, it can be found that the second light control parts of Examples 2 and 3 show reduced reflectance of SCI. Referring to FIG. 10, compared to the light control part of the Comparative Example, it can be found that the second light control parts of Examples 2 and 3 show reduced reflectance of SCE. Accordingly, it can be found that the second light control part including the metal nanomaterial according to an embodiment reduces reflectance and may improve the display quality of the display device.

Table 1 shows relative reflectance in the display devices of the Examples and Comparative Example, measured using CM-3700A (product of KONICA MINOLTA Inc.). The Comparative Example, Example 2 and Example 3 in Table 1 are the same as the Comparative Example, Example 2 and Example 3 in FIG. 9 and FIG. 10. In Table 1, “SCI reflectance” represents a relative value with the SCI reflectance of the Comparative Example as 100%. “SCE reflectance” represents a relative value with the SCE reflectance of the Comparative Example as 100%.

In Table 1, Example 4 includes the second light control part including green quantum dots and orange quantum dots according to an embodiment. In Example 4, each of the green quantum dots and the orange quantum dots includes InP. In Example 4, the weight of the orange quantum dots is about 2 wt % on the basis of about 100 wt % of the total weight of the second control part. Example 4 is a second light control part including the metal nanomaterial according to an embodiment and satisfies the above-described weight range (i.e., about 0.1 wt % to about 15 wt %).

TABLE 1

| | Comparative | Example 4 | Example 2 | Example 3 (8 |
|---|---|---|---|---|
| | Example | (2 wt %) | (4 wt %) | wt %) |
| SCI | 100.0% | 99.6% | 99.1% | 97.6% |
| reflectance | | | | |
| SCE | 100.0% | 99.5% | 98.9% | 97.9% |
| reflectance | | | | |

Referring to Table 1, compared to the display device of the Comparative Example, it can be found that the display devices of Examples 2 to 4 show reduced reflectance. As described above, Examples 2 to 4 include the second light control part including the green quantum dots and the metal nanomaterial according to an embodiment. Accordingly, in an embodiment, it can be found that the display device including the second light control part including the metal nanomaterial and the green quantum dot shows reduced reflectance and excellent display quality.

The display device of an embodiment may include a light control part disposed on a light emitting element. The light control part may include green quantum dots and a metal nanomaterial, and the metal nanomaterial may absorb light in a wavelength range of about 550 nm to about 590 nm. Accordingly, the light control part may reduce reflectance, while maintaining excellent light efficiency. The display device including the light control part according to an embodiment may have excellent display quality.

The display device of an embodiment may include a metal nanomaterial that absorbs light in a certain wavelength range and reduces reflectance, thereby having excellent display quality.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display element layer comprising a light emitting element; and
a light control layer disposed on the display element layer and comprising:
a first light control part comprising first quantum dots; and
a second light control part that is separated from the first light control part in a direction that is perpendicular to a thickness direction and comprising second quantum dots and a metal nanomaterial, wherein
the first quantum dots emit light in a wavelength range of about 630 nm to about 750 nm,
the second quantum dots emit light in a wavelength range of about 495 nm to about 570 nm, and
the metal nanomaterial absorbs light in a wavelength range of about 550 nm to about 590 nm.

2. The display device of claim 1, wherein the metal nanomaterial emits light in a wavelength range of about 550 nm to about 630 nm.

3. The display device of claim 1, wherein the metal nanomaterial has a light emitting central wavelength in a wavelength range of about 580 nm to about 630 nm.

4. The display device of claim 1, wherein the metal nanomaterial comprises at least one of yellow quantum dots, orange quantum dots, gold nanoparticles, silver nanoparticles, and silver nanoplates.

5. The display device of claim 4, wherein a diameter of each of the gold nanoparticles, the silver nanoparticles, and the silver nanoplates is in a range of about 10 nm to about 800 nm.

6. The display device of claim 1, wherein a weight of the metal nanomaterial is in a range of about 0.1 wt % to about 15 wt % on a basis of 100 wt % of a total weight of the second light control part.

7. The display device of claim 1, wherein
an absorption spectrum of the metal nanomaterial comprises a wavelength variation region in a wavelength range of about 520 nm to about 540 nm, and
the wavelength variation region is a region with a concave shape in the absorption spectrum, where an absorbance decreases and increases.

8. The display device of claim 1, wherein a weight of the second quantum dots is in a range of about 10 wt % to about 50 wt % on a basis of 100 wt % of a total weight of the second light control part.

9. The display device of claim 1, wherein
each of the first light control part and the second light control part further comprises a scatterer, and
the scatterer comprises at least one of TiO₂, SiO₂, BaTiO₃, BaO, ZnS, ZnO, Al₂O₃, and hollow silica.

10. The display device of claim 9, wherein a weight of the scatterer is in a range of about 0 wt % to about 15 wt % on a basis of 100 wt % of a total weight of the second light control part.

11. The display device of claim 9, wherein
the scatterer comprises a plurality of scatterers, and
a median diameter (D50) of the plurality of scatterers is in a range of about 50 nm to about 500 nm.

12. The display device of claim 1, wherein each of the first quantum dots, the second quantum dots, and the metal nanomaterial comprises at least one of a II-VI group semiconductor compound, a I-II-VI group semiconductor compound, a II-IV-VI group compound, a I-II-IV-VI group semiconductor compound, a III-V group semiconductor compound, a III-II-V group semiconductor compound, a III-VI group semiconductor compound, a I-III-VI group semiconductor compound, a IV-VI group semiconductor compound, a II-IV-V group semiconductor compound, a IV group semiconductor compound, a IV group element, a mixture thereof, and a compound thereof.

13. The display device of claim 1, wherein each of the first quantum dots and the second quantum dots comprises a core and a shell surrounding the core.

14. The display device of claim 1, wherein the light emitting element comprises a first electrode, a second electrode disposed on the first electrode, and an emission layer that is disposed between the first electrode and the second electrode and emits source light comprising blue light and green light.

15. A display device comprising:
a display element layer providing source light; and
a light control layer disposed on the display element layer and comprising:
a first light control part comprising red quantum dots; and
a second light control part that is separated from the first light control part in a direction that is perpendicular to a thickness direction and comprising green quantum dots and a metal nanomaterial, wherein
the metal nanomaterial comprises at least one of yellow quantum dots, orange quantum dots, gold nanoparticles, silver nanoparticles, and silver nanoplates.

16. The display device of claim 15, wherein the metal nanomaterial absorbs light in a wavelength range of about 550 nm to about 590 nm.

17. The display device of claim 15, wherein
an absorption spectrum of the metal nanomaterial comprises a wavelength variation region in a wavelength range of about 520 nm to about 540 nm, and
the wavelength variation region is a region with a concave shape in the absorption spectrum, where an absorbance decreases and increases.

18. The display device of claim 15, wherein the metal nanomaterial has a light emitting central wavelength in a wavelength range of about 580 nm to about 630 nm.

19. The display device of claim 15, wherein a diameter of each of the gold nanoparticles, the silver nanoparticles, and the silver nanoplates is in a range of about 10 nm to about 800 nm.

20. The display device of claim 15, wherein a weight of the metal nanomaterial is in a range of about 0.1 wt % to about 15 wt % on a basis of 100 wt % of a total weight of the second light control part.

21. The display device of claim 15, wherein the source light comprises blue light and green light.

22. The display device of claim 15, wherein
each of the first light control part and the second light control part further comprises a scatterer, and
the scatterer comprises at least one of TiO₂, SiO₂, BaTiO₃, BaO, ZnS, ZnO, Al₂O₃, and hollow silica.

23. A display device divided into a red pixel area, a green pixel area, and a blue pixel area, comprising:
a display element layer comprising a light emitting element; and
a light control layer disposed on the display element layer and comprising:
a first light control part comprising first quantum dots and corresponding to the red pixel area;
a second light control part comprising second quantum dots and a metal nanomaterial, and corresponding to the green pixel area; and
a third light control part corresponding to the blue pixel area,
wherein the metal nanomaterial absorbs light in a wavelength range of about 550 nm to about 590 nm.

24. The display device of claim 23, wherein the metal nanomaterial comprises at least one of yellow quantum dots, orange quantum dots, gold nanoparticles, silver nanoparticles, and silver nanoplates.
